(19) United States
(12) Patent Application Publication
(10) Pub. No.: US 2013/0241638 A1
(43) Pub. Date: Sep. 19, 2013

(54) SIGNAL AMPLIFIER CIRCUIT FOR USB PORT

(71) Applicants: ZHI-MING ZHU, Wuhan (CN); TING WANG, Wuhan (CN)

(72) Inventors: ZHI-MING ZHU, Wuhan (CN); TING WANG, Wuhan (CN)

(21) Appl. No.: 13/678,684

(22) Filed: Nov. 16, 2012

(30) Foreign Application Priority Data
Mar. 16, 2012 (CN) 201210070015.6

(51) Int. Cl. H03F 3/45

(52) U.S. Cl. CPC H03F 3/45
USPC 330/69

(57) ABSTRACT

A signal amplifier circuit for USB port includes a USB controller, an amplifier circuit, a USB port and a signal regulator circuit. The USB controller includes a super speed transmitter differential pair and a super speed receiver differential pair. The amplifier circuit includes two first input terminals, two second input terminals, two first output terminals, and two second output terminals. The USB port includes two first differential signal receiving terminals and two first differential signal transmitting terminals. The super speed transmitter differential pair and the super speed receiver differential pair are electrically connected to the first input terminals and the second output terminals. The first output terminals and the second input terminals are electrically connected to the first differential signal receiving terminals and the first differential signal transmitting terminals. The signal regulator circuit regulates amplitude and jitter of differential signals amplified by the amplifier circuit.

### CROSS-REFERENCE TO RELATED APPLICATION

The present application related in a co-pending U.S. patent application entitled “SIGNAL AMPLIFIER CIRCUIT FOR USB PORT,” Attorney Docket Number US43306, simultaneously filed with the present application.

### BACKGROUND

1. Technical Field

The present disclosure relates to a signal amplifier circuit for USB ports.

2. Description of Related Art

Universal serial bus (USB) technology is broadly applied as a solution to serial communications. The USB 3.0 specification was published on 12 Nov. 2008. The USB 3.0 specification's main goals were to increase the data transfer rate (up to 5 Gbit/s), to decrease power consumption, to increase power output, and to be backwards-compatible with USB 2.0. USB 3.0 includes a new, higher speed bus called super speed connected in parallel with the USB 2.0 bus. The signals usually tend to attenuate in USB 3.0 during transmission for a long distance on printed circuit boards. Therefore, the quality of the signals is affected.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a signal amplifier circuit for USB port.

FIG. 2 is a circuit diagram of the signal amplifier circuit of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

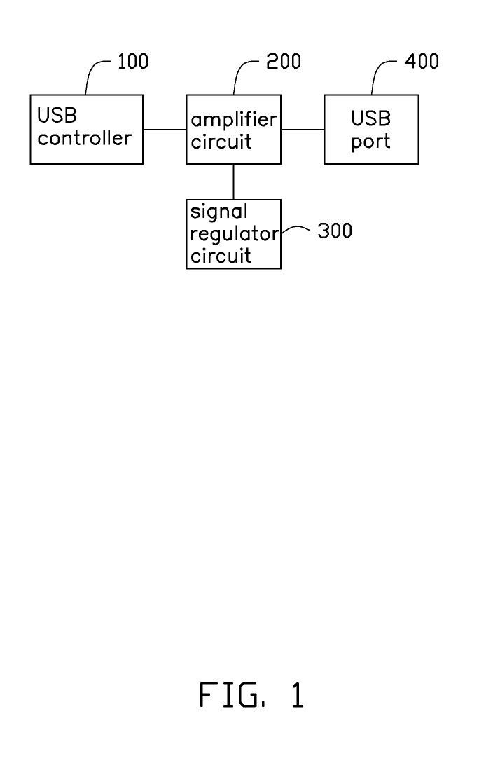

FIG. 1 illustrates a block diagram of a signal amplifier circuit for USB ports in accordance with one embodiment. The signal amplifier circuit includes a USB controller 100, an amplifier circuit 200, a signal regulator circuit 300, and a USB port 400. The amplifier circuit 200 amplifies differential signals transmitted between the USB controller 100 and the USB port 300. The signal regulator circuit 300 regulates amplitude and jitter of differential signals amplified by the amplifier circuit 200. In one embodiment, the USB port 300 is a USB 3.0 port.

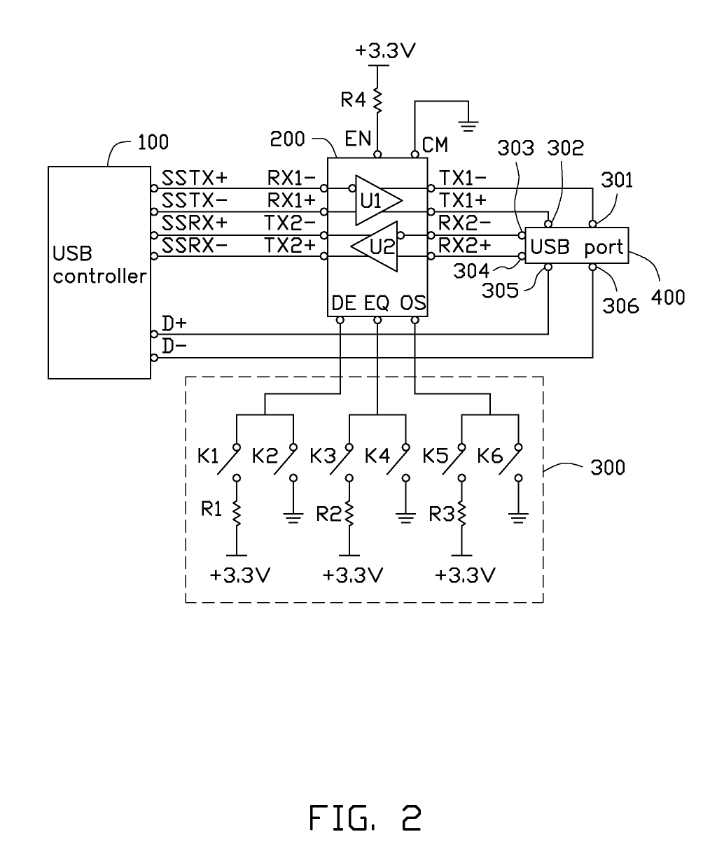

FIG. 2 illustrates a circuit diagram of the signal amplifier circuit in accordance with one embodiment. The USB controller 100 includes a super speed transmitter differential pair SSTX+, SSTX−, a super speed receiver differential pair SSRX+, SSRX−, and two first differential signal receiving and transmitting terminals D+, D−. The amplifier circuit 200 includes two first input terminals RX1+, RX1−, two second input terminals RX2+, RX2−, two first output terminals TX1+, TX1−, two second output terminals TX2+, TX2−, a de-emphasis regulating terminal DE, an equalization regulating terminal EQ, an amplitude regulating terminal OS, an enable terminal EN, and an operation terminal CM.

The signal regulator circuit 300 includes a first signal regulating unit, a second signal regulating unit, and a third signal regulating unit. The first signal regulating unit includes switches K1, K2 and resistor R1. The de-emphasis regulating terminal DE is electrically connected to a DC voltage via the switch K1 and the resistor R1 connected in series. The de-emphasis regulating terminal DE is grounded via the switch K2. The second signal regulating unit includes switches K3, K4 and resistor R2. The equalization regulating terminal EQ is electrically connected to the DC voltage via the switch K3 and the resistor R2 connected in series. The equalization regulating terminal EQ is grounded via the switch K4. The third signal regulating unit includes switches K5, K6 and resistor R3. The amplitude regulating terminal OS is electrically connected to the DC voltage via the switch K5 and the resistor R3 connected in series. The amplitude regulating terminal OS is grounded via the switch K6. The enable terminal EN is electrically connected to the DC voltage via a resistor R4. The operation terminal CM is grounded. In one embodiment, the DC voltage is +3.3V.

The USB port 400 includes two first differential signal receiving terminals 401, 402, two first differential signal transmitting terminals 403, 404, and two second differential signal receiving and transmitting terminals 405, 406. The super speed transmitter differential pair SSTX+, SSTX− is electrically connected to the first input terminals RX1−, RX1+. The super speed receiver differential pair SSRX+, SSRX− is electrically connected to the second output terminals TX2−, TX2+. The first output terminals TX1−, TX1+ are electrically connected to the first differential signal receiving terminals 401, 402. The second input terminals RX2−, RX2+ are electrically connected to the first differential signal transmitting terminals 403, 404. The first differential signal receiving and transmitting terminals D+, D− are electrically connected to the second differential signal receiving and transmitting terminals 405, 406.

The amplifier circuit 200 includes a first amplifier U1 and a second amplifier U2. The first amplifier U1 is electrically connected to the first input terminals RX1−, RX1+ and the first output terminals TX1−, TX1+. The second amplifier U2 is electrically connected to the second input terminals RX2−, RX2+ and the second output terminals TX2−, TX2+. In one embodiment, the first differential signal receiving and transmitting terminals D+, D− and the second differential signal receiving and transmitting terminals 405, 406 support the USB 2.0 specification. The super speed transmitter differential pair SSTX+, SSTX− and the super speed receiver differential pair SSRX+, SSRX− support the USB 3.0 specification.

In application, the data of USB 3.0 specification stored in the USB controller 100 is transmitted to the first amplifier U1 from the super speed transmitter differential pair SSTX+, SSTX− to the first input terminals RX1−, RX1+. The data of USB 3.0 is amplified by the first amplifier U1 and is then transmitted to the USB port 400 from the first output terminals TX1−, TX1+ to the first differential signal receiving terminals 401, 402. The data of USB 3.0 specification from the USB port 400 is transmitted to the second amplifier U2 via the second input terminals RX2−, RX2+. The data of USB 3.0 is amplified by the second amplifier U2 and is then transmitted to the USB controller 100 from the second output terminals TX2−, TX2+ to the super speed receiver differential pair SSRX+, SSRX−. The data of USB 2.0 specification stored in the USB controller 100 is transmitted to the USB port 400 from the first differential signal receiving and transmitting terminals D+, D− to the second differential signal receiving and transmitting terminals 405, 406. The data of USB 2.0 specification from the USB port 400 is transmitted to the USB controller 100 via the second differential signal receiving and transmitting terminals 405, 406 to the first differential signal receiving and transmitting terminals D+, D−.

In one embodiment, when the switches K1, K3, and K5 are closed, the amplifier circuit 200 receives a high voltage level regulating signal via the de-emphasis regulating terminal DE, the equalization regulating terminal EQ, and the amplitude regulating terminal OS. When the switches K2, K4, and K6 are closed, the amplifier circuit 200 receives a low voltage level regulating signal via the de-emphasis regulating terminal DE, the equalization regulating terminal EQ, and the amplitude regulating terminal OS. The amplifier circuit 200 regulates the amplified differential signals according to the high voltage level and low voltage level regulating signals.

Even though numerous characteristics and advantages of the present disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A signal amplifier circuit for USB port comprising:
a USB controller comprising a super speed transmitter differential pair and a super speed receiver differential pair;
an amplifier circuit comprising two first input terminals, two second input terminals, two first output terminals, and two second output terminals;
a USB port comprising two first differential signal receiving terminals and two first differential signal transmitting terminals; wherein the super speed transmitter differential pair and the super speed receiver differential pair are electrically connected to the two first input terminals and the two second output terminals, respectively; the two first output terminals and the two second input terminals are electrically connected to the two first differential signal receiving terminals and the two first differential signal transmitting terminals, respectively; the amplifier circuit is adapted to amplify differential signals transmitted between the USB controller and the USB port; and
a signal regulator circuit adapted to regulate amplitudes and jitters of the differential signals amplified by the amplifier circuit.

2. The signal amplifier circuit of claim 1, wherein the amplifier circuit further comprises a first amplifier and a second amplifier; the first amplifier is electrically connected to the two first input terminals and the two first output terminals; and the second amplifier is electrically connected to the two second input terminals and the two second output terminals.

3. The signal amplifier circuit of claim 2, wherein the super speed transmitter differential pair comprises a super speed transmitter positive differential terminal and a super speed transmitter negative differential terminal; and the super speed receiver differential pair comprises a super speed receiver positive differential terminal and a super speed receiver negative differential terminal.

4. The signal amplifier circuit of claim 3, wherein the USB controller further comprises two first differential signal receiving and transmitting terminals; the USB port further comprises two second differential signal receiving and transmitting terminals; and each of the two first differential signal receiving and transmitting terminals is electrically connected to each of the two second differential signal receiving and transmitting terminals.

5. The signal amplifier circuit of claim 4, wherein each of the two first differential signal receiving and transmitting terminal comprises a first differential signal receiving and transmitting positive terminal and a first differential signal receiving and transmitting negative terminal; and each of the two second differential signal receiving and transmitting terminal comprises a second differential signal receiving and transmitting positive terminal and a second differential signal receiving and transmitting negative terminal.

6. The signal amplifier circuit of claim 5, wherein the signal regulator circuit includes a plurality of signal regulating units; each of the plurality of signal regulating units comprises a first switch, a second switch, and a first resistor; the amplifier circuit further comprises at least one signal regulating terminal; the at least one signal regulating terminal is electrically connected to a DC voltage via the first switch and the first resistor connected in series; and the at least one signal regulating terminal is grounded via the second switch.

7. The signal amplifier circuit of claim 6, wherein when the first switch is closed, the amplifier circuit receives a high voltage level regulating signal via the at least one signal regulating terminal; when the second switch is closed, the amplifier circuit receives a low voltage level regulating signal via the at least one signal regulating terminal; and the amplifier circuit is adapted to regulate the differential signals which are amplified according to the high voltage level and low voltage level regulating signals, wherein the high voltage level regulating signals has a higher voltage than the low voltage level regulating signal.

8. The signal amplifier circuit of claim 7, wherein the amplifier circuit further comprises an enable terminal and an operation terminal; the enable terminal is electrically connected to the DC voltage via a second resistor; and the operation terminal is grounded.

9. The signal amplifier circuit of claim 4, wherein the two first differential signal receiving and transmitting terminals and the two second differential signal receiving and transmitting terminals support USB 2.0 specification.

10. The signal amplifier circuit of claim 1, wherein the super speed transmitter differential pair and the super speed receiver differential pair support USB 3.0 specification.

11. A signal amplifier circuit for USB port comprising:
a USB controller comprising a super speed transmitter differential pair and a super speed receiver differential pair;
an amplifier circuit comprising a first amplifier, a second amplifier, two first input terminals, two second input terminals, two first output terminals, and two second output terminals; wherein the first amplifier is electrically connected to the two first input terminals and the two first output terminals; and the second amplifier is electrically connected to the two second input terminals and the two second output terminals;
a USB port comprising two first differential signal receiving terminals and two first differential signal transmitting terminals; wherein the super speed transmitter differential pair and the super speed receiver differential pair are electrically connected to the two first input terminals and the two second output terminals, respectively; the two first output terminals and the two second input terminals are electrically connected to the two first differential signal receiving terminals and the two first differential signal transmitting terminals, respectively; the amplifier circuit is adapted to amplify differential signals transmitted between the USB controller and the USB port; and
a signal regulator circuit adapted to regulate amplitudes and jitters of differential signals amplified by the amplifier circuit.

12. The signal amplifier circuit of claim 11, wherein the super speed transmitter differential pair comprises a super speed transmitter positive differential terminal and a super speed transmitter negative differential terminal; and the super speed receiver differential pair comprises a super speed receiver positive differential terminal and a super speed receiver negative differential terminal.

13. The signal amplifier circuit of claim 12, wherein the USB controller further comprises two first differential signal receiving and transmitting terminals; the USB port further comprises two second differential signal receiving and transmitting terminals; and each of the two first differential signal receiving and transmitting terminals is electrically connected to each of the two second differential signal receiving and transmitting terminals.

14. The signal amplifier circuit of claim 13, wherein each of the two first differential signal receiving and transmitting terminals comprises a first differential signal receiving and transmitting positive terminal and a first differential signal receiving and transmitting negative terminal; and each of the two second differential signal receiving and transmitting terminals comprises a second differential signal receiving and transmitting positive terminal and a second differential signal receiving and transmitting negative terminal.

15. The signal amplifier circuit of claim 14, wherein the signal regulator circuit includes a plurality of signal regulating units; each of the plurality of signal regulating units comprises a first switch, a second switch, and a first resistor; the amplifier circuit further comprises at least one signal regulating terminal; the at least one signal regulating terminal is electrically connected to a DC voltage via the first switch and the first resistor connected in series; and the at least one signal regulating terminal is grounded via the second switch.

16. The signal amplifier circuit of claim 15, wherein when the first switch is closed, the amplifier circuit receives a high voltage level regulating signal via the at least one signal regulating terminal; when the second switch is closed, the amplifier circuit receives a low voltage level regulating signal via the at least one signal regulating terminal; and the amplifier circuit is adapted to regulate the differential signals which are amplified according to the high voltage level and low voltage level regulating signals, wherein the high voltage level regulating signals has a higher voltage than the low voltage level regulating signal.

17. The signal amplifier circuit of claim 16, wherein the amplifier circuit further comprises an enable terminal and an operation terminal; the enable terminal is electrically connected to the DC voltage via a second resistor; and the operation terminal is grounded.

18. The signal amplifier circuit of claim 13, wherein the two first differential signal receiving and transmitting terminals and the two second differential signal receiving and transmitting terminals support USB 2.0 specification.

19. The signal amplifier circuit of claim 11, wherein the super speed transmitter differential pair and the super speed receiver differential pair support USB 3.0 specification.
